(19) United States
(12) Patent Application Publication
(10) Pub. No.: US 2015/0331055 A1
(43) Pub. Date: Nov. 19, 2015

(54) VEHICLE CONTROL APPARATUS

(71) Applicant: TOYOTA JIDOSHA KABUSHIKI KAISHA, Toyota-shi (JP)

(72) Inventors: Yuhei OI, Miyoshi-shi (JP); Koji ITO, Nagoya-shi (JP); Hiroshi SATO, Nagoya-shi (JP); Kazuhiko SAKAKIBARA, Toyota-shi (JP)

(73) Assignee: TOYOTA JIDOSHA KABUSHIKI KAISHA, Toyota-shi (JP)

(21) Appl. No.: 14/678,124

(22) Filed: Apr. 3, 2015

(30) Foreign Application Priority Data
May 16, 2014 (JP) 2014-102753

(51) Int. Cl. G01R 31/36; G01R 31/00

(52) U.S. Cl. CPC G01R 31/3606; G01R 31/005; G01R 31/3648

(57) ABSTRACT

A vehicle control apparatus is provided, which includes a sensor; and a processing device that calculates a SOC, determines whether the calculation value of the SOC is greater than a predetermined threshold, and permits execution of control that involves a discharge of a battery if the SOC is greater than the predetermined threshold. When the processing device detects a decrease in accuracy of the SOC, the processing device determines whether the calculation value of the SOC at a time of detection of the decrease is greater than a predetermined value, and if yes, corrects the SOC, etc., to continue the determination with the predetermined threshold, such that the execution of the control is permitted more difficulty, within a range in which the execution of the control can be permitted, with respect to a state before the detection.

### FIELD

The disclosure is related to a vehicle control apparatus.

### BACKGROUND

Japanese Laid-open Patent Publication No. 05-087896 (Patent Document 1) discloses a battery rest quantity detection/correction method that includes a consumed electric current calculation part for accumulating the consumed electric current supplied from a battery and a battery rest quantity correction part for correcting the battery rest quantity calculation value at each prescribed voltage which is obtained from the value accumulated by the consumed electric current calculation part, based on the actual battery rest quantity at each prescribed voltage of the battery.

It is useful to suppress control that involves a discharge of a battery (fuel economy control such as charge control, idling stop control, for example) in terms of a battery reservation, if a SOC (State Of Charge) of the battery becomes less than a predetermined level.

The SOC of the battery is calculated from a current accumulation value, etc., based on sensor information, and thus there may be a case where accuracy of a calculation value (estimation value) of the SOC is decreased. If an execution of the control that involves the discharge of the battery is permitted based on the calculation value with the decreased accuracy, there may be a risk that an actual SOC of the battery decreases below a lower limit value, leading to an undesired case in terms of the battery reservation. For this reason, there may be such a solution in which, if the calculation accuracy of the SOC of the battery is decreased, the execution of the control that involves the discharge of the battery may be prevented until a correction value suited for a decreased accuracy state is obtained. However, according to such a solution, there may be a risk that a chance to execute the control that involves the discharge of the battery may be limited more than necessary.

Therefore, the disclosure is to provide a vehicle control apparatus that is capable of appropriately reducing a limitation on an execution of control that involves a discharge of a battery when a decrease in accuracy of a calculation value of a SOC is detected.

### SUMMARY

According to one aspect of the disclosure, a vehicle control apparatus is provided, which includes:
a sensor that obtains information related to a SOC (State Of Charge) of a battery; and
a processing device that calculates the SOC based on the information from the sensor; determines whether the calculation value of the SOC is greater than a predetermined threshold; and permits an execution of control that involves a discharge of the battery if the calculation value of the SOC is greater than the predetermined threshold, wherein
when the processing device detects a decrease in accuracy of the calculation value of the SOC, the processing device determines whether the calculation value of the SOC at a time of detection of the decrease is greater than a predetermined value that is greater than the predetermined threshold, and if the calculation value of the SOC at a time of detection of the decrease is greater than the predetermined value, the processing device corrects at least one of the calculation value of the SOC and the predetermined threshold to continue the determination with the predetermined threshold, wherein at least one of the calculation value of the SOC and the predetermined threshold is corrected such that the execution of the control is permitted more difficulty, within a range in which the execution of the control can be permitted, with respect to a state before the detection of the decrease.

### BRIEF DESCRIPTION OF DRAWINGS

FIG. 1 is a diagram illustrating a configuration of a power supply system of a vehicle according an embodiment.

FIG. 2 is a diagram illustrating a system configuration of a control system of a vehicle according an embodiment.

FIG. 3 is a diagram illustrating an example of a functional configuration of a battery capacity calculation part 14.

FIG. 4 is a diagram for explaining a first correction value Δ1 for high accuracy state and a second correction value Δ2 for low accuracy state.

FIG. 5 is an example of a flowchart of a process executed by a charge control ECU 10.

FIG. 6 is a diagram illustrating an example of a change in time series of a control SOC based on an accuracy reservation margin M and a control SOC for high accuracy state.

FIG. 7 is a diagram illustrating an example of a change in time series of the control SOC in a high accuracy state and a low accuracy state.

FIG. 8 is a timing chart illustrating an example of a way of calculating the second correction value Δ2 for the low accuracy state based on behavior of a charge current I of a battery 60.

### DESCRIPTION OF EMBODIMENTS

In the following, embodiments will be described with reference to the accompanying drawings.

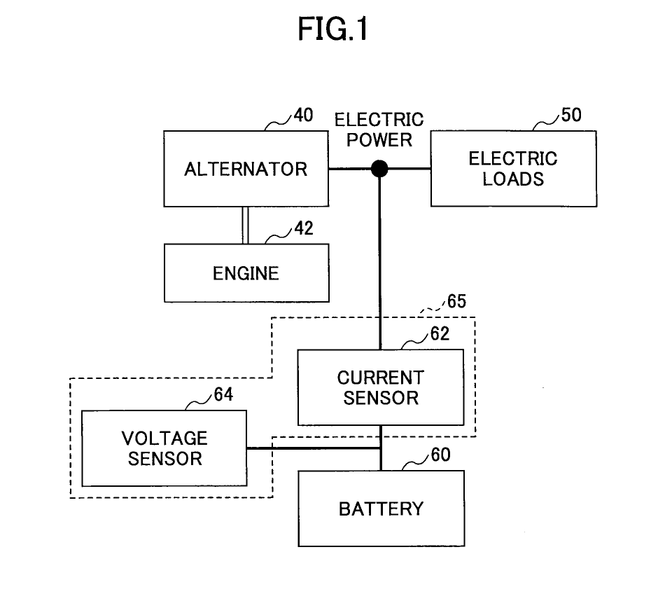

FIG. 1 is a diagram for illustrating a configuration of a power supply system of a vehicle according an embodiment. The embodiment is suited for the vehicle that has only an engine installed as a power source (i.e., other than hybrid vehicles and electric vehicles), as illustrated in FIG. 1. In a configuration illustrated in FIG. 1, an alternator 40 is mechanically connected to an engine 42. The alternator 40 is a generator that generates electricity based on power of the engine 42. The electric power generated by the alternator 40 is utilized for charging a battery 60 and driving vehicle electric loads 50. It is noted that a current sensor 62 is provided for the battery 60. The current sensor 62 detects a battery current (i.e., a charge current to the battery 60 and a discharge current from the battery 60). Typically, the battery 60 is a lead acid battery; however, other types of batteries (or capacitors) may be used. A voltage sensor 64 is provided for the battery 60. It is noted that the voltage sensor 64 and the current sensor 62 may be formed by a single sensor unit 65 in which the voltage sensor 64 and the current sensor 62 are incorporated together with a processor (a microcomputer, for example). The sensor unit 65 may be a sensor that is referred to as an intelligent battery sensor or the like, for example. Further, the current sensor 62 may be a shunt resistance, for example, and the voltage may be calculated based on a product of the current value detected by the current sensor 62 and a resistance value of the shunt resistance. In this case, the current sensor 62 also serves as the voltage sensor 64. The vehicle electric loads 50 are arbitrary, and include a starter, an air conditioner, a wiper, etc. In such a configuration, by controlling a voltage generated by the alternator 40, a SOC (State Of Charge) of the battery 60 can be controlled.

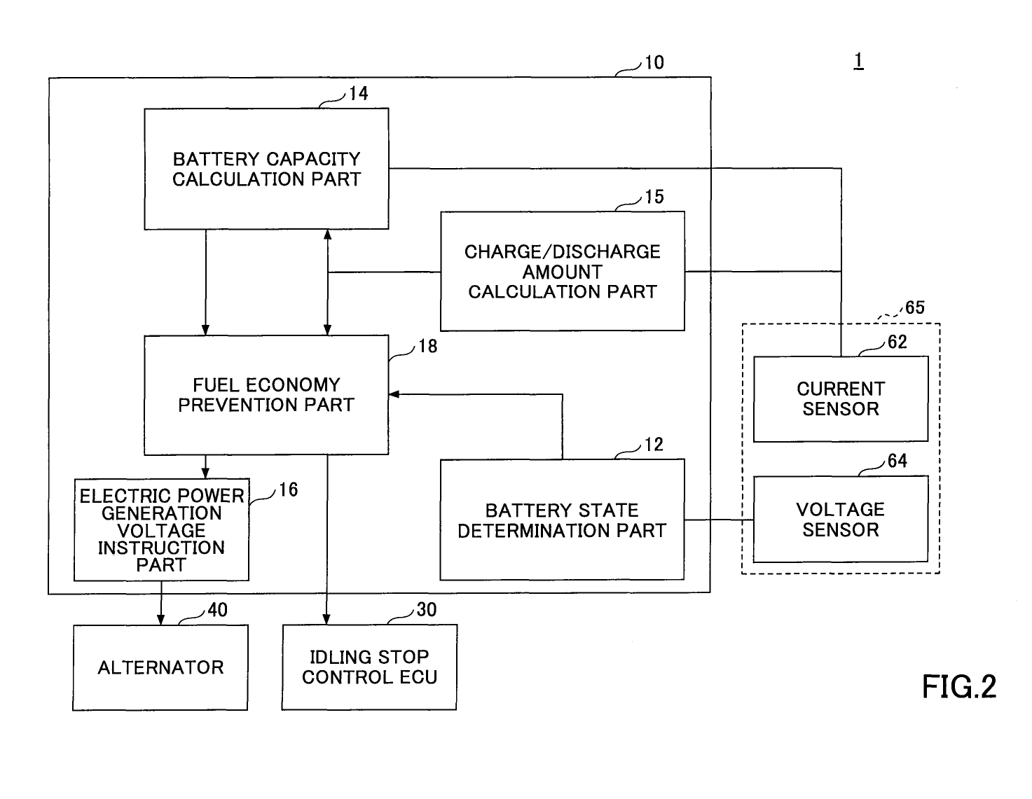

FIG. 2 is a diagram illustrating a system configuration of a control system of a vehicle according an embodiment.

A control system 1 includes a charge control ECU (Electronic Control Unit) 10 and an idling stop control ECU 30. It is noted that connection ways between elements in FIG. 2 are arbitrary. For example, the connection ways may include a connection via a bus such as a CAN (controller area network), etc., an indirect connection via another ECU, etc., a direct connection, and a connection that enables wireless communication. It is noted that sections of the functions of the ECUs are arbitrary, and a part or all of the functions of a particular ECU may be implemented by another ECU (which may include an ECU not illustrated). For example, a part or all of the functions of the charge control ECU 10 may be implemented by the idling stop control ECU 30, or reversely a part or all of the functions of the idling stop control ECU 30 may be implemented by the charge control ECU 10. Further, if the sensor unit 65 in which a microcomputer is incorporated is used, a part of a function of the charge control ECU 10 may be implemented by the microcomputer in the sensor unit 65. For example, a part of or all of a battery capacity calculation part 14 may be implemented by the microcomputer in the sensor unit 65.

The charge control ECU 10 may be implemented by an engine ECU for controlling the engine, for example. The charge control ECU 10 includes a battery state determination part 12, a battery capacity calculation part 14, a charge/discharge amount calculation part 15, an electric power generation voltage instruction part 16 and a fuel economy prevention part 18, as illustrated in FIG. 2. It is noted that these parts merely represent functions implemented by software resources, and the sections are also arbitrary. Thus, a part of or all of a program that implements the battery state determination part 12 and/or the charge/discharge amount calculation part 15, for example, may be incorporated into a program that implements the battery capacity calculation part 14.

The battery state determination part 12 determines a degradation degree of the battery 60. Ways of determining the degradation degree of the battery 60 are various, and an arbitrary way may be used. For example, the degradation degree of the battery 60 is related to an internal resistance of the battery 60, and thus the degradation degree of the battery 60 may be calculated according to the internal resistance of the battery 60.

The battery capacity calculation part 14 calculates the current SOC of the battery 60. The battery capacity calculation part 14 outputs a control SOC based on the calculated SOC of the battery 60. Details of the battery capacity calculation part 14 are described hereinafter.

The charge/discharge amount calculation part 15 calculates a cumulative charge/discharge electricity amount based on the detection values of the current sensor 62. The cumulative charge/discharge electricity amount may be a time-integrated value of the charge current and the discharge current such that the charge current and the discharge current are integrated with absolute values thereof. In the following, as an example, it is assumed that the charge/discharge amount calculation part 15 calculates the cumulative charge/discharge electricity amount from the time of the ignition switch ON event. In other words, the cumulative charge/discharge electricity amount is reset to an initial value 0 when the ignition switch is turned off.

The electric power generation voltage instruction part 16 performs charge control under a situation where the charge control is not prevented by fuel economy prevention part 18 as described hereinafter. Specifically, the electric power generation voltage instruction part 16 determines a power generation voltage (target value) of the alternator 40 based on a vehicle traveling state, and the control SOC calculated in the battery capacity calculation part 14. The vehicle travel state includes a vehicle stop state, an accelerated state, a constant vehicle speed state, a decelerated state, etc., for example. A way of determining the electric power generation voltage of the alternator according to the vehicle travel state is arbitrary. For example, in the constant vehicle speed state in which the vehicle speed is substantially constant, the electric power generation voltage instruction part 16 instructs the electric power generation voltage of the alternator 40 such that the control SOC is kept at a constant value a (smaller than 100%). Further, in the accelerated state, the electric power generation voltage instruction part 16 stops the electric power generation of the alternator 40 to increase an accelerating ability. In the decelerated state, the electric power generation voltage instruction part 16 performs an electric power regenerating operation of the alternator 40. It is noted that, when an idling stop control is performed in the vehicle stop state, the alternator 40 is stopped during a period in which the idling stop control is being performed.

The electric power generation voltage instruction part 16 instructs a predetermined constant value as the electric power generation voltage of the alternator 40, regardless of the vehicle travel state, etc., in a situation where the charge control is prevented by the fuel economy prevention part 18 as described hereinafter. The predetermined constant value may be set such that the battery 60 is brought to its fully charged state and kept in the fully charged state, for example. Alternatively, the electric power generation voltage instruction part 16 may instruct the electric power generation voltage of the alternator 40 such that the control SOC calculated by the battery capacity calculation part 14 become 100%.

The fuel economy prevention part 18 performs a process (referred to as “a fuel economy control execution propriety determination process” hereinafter) for determining whether an execution of the fuel economy control can be performed. Specifically, the fuel economy prevention part 18 determines whether the control SOC becomes less than or equal to a predetermined threshold (referred to as “a control permission SOC”, hereinafter). The fuel economy prevention part 18 outputs a prevention instruction for preventing the execution of the fuel economy control if the control SOC becomes less than or equal to the control permission SOC. The fuel economy control is performed for the purpose of increasing the fuel economy. The fuel economy control includes a charge control and an idling stop (Stop and Start) control, in this example. Thus, in this example, the fuel economy prevention part 18 prevents the charge control and the idling stop control by the idling stop control ECU 30, if the control SOC becomes less than or equal to the control permission SOC.

Further, the fuel economy prevention part 18 outputs the prevention instruction for preventing the fuel economy control during a refresh charging. In other words, the fuel economy prevention part 18 prevents the charge control and the idling stop control by the idling stop control ECU 30 during the refresh charging. A way of performing the refresh charging is arbitrary. Typically, the refresh charging includes charging the battery 60 to reach a charge late state in which the charge current of the battery 60 becomes less than a predetermined value or an overcharged state. A start condition of the refresh charging is arbitrary. In the present embodiment, the start condition of the refresh charging is met if it becomes necessary to perform a calculation process for calculating a second correction value Δ2 for low accuracy state (described hereinafter). Further, the refresh charging may be performed if the degradation degree of the battery 60 determined by the battery state determination part 12 exceeds a predetermined threshold, etc.

The idling stop control ECU 30 performs the idling stop control. The idling stop control is also referred to as “S & S (Stop & Start)”. The details of the idling stop control are arbitrary. Typically, the idling stop control stops the engine 42 when a predetermined idling stop start condition is met in the vehicle stop state or the decelerated state in a low-speed range, and then restarts the engine 42 when a predetermined idling stop end condition is met. The predetermined idling stop start condition includes a condition where a prevention instruction is not output from the fuel economy prevention part 18. In other words, if the prevention instruction is generated by the fuel economy prevention part 18 (i.e., the fuel economy control is prevented by the fuel economy prevention part 18), the idling stop control is also prevented and thus is not performed.

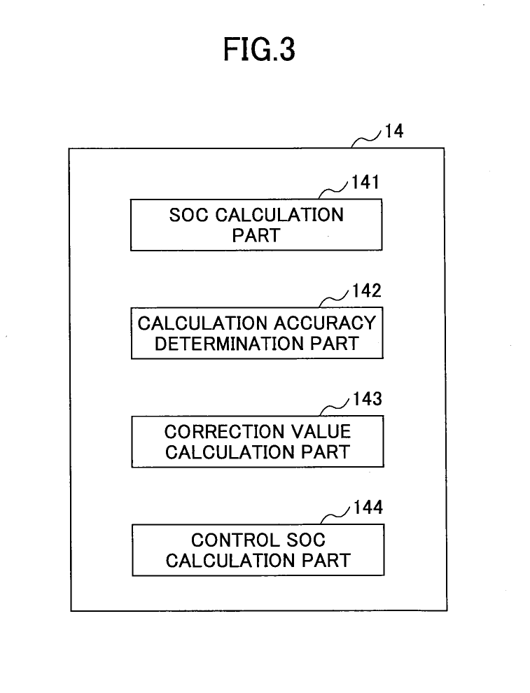

FIG. 3 is a diagram illustrating an example of a functional configuration of a battery capacity calculation part 14.

The battery capacity calculation part 14 includes a SOC calculation part 141, a calculation accuracy determination part 142, a correction value calculation part 143, and a control SOC calculation part 144.

The SOC calculation part 141 calculates the current SOC of the battery 60 based on the detection values of the current sensor 62, etc. A concrete way of calculating the SOC of the battery 60 may be arbitrary. For example, the current SOC of the battery 60 can be calculated based on the SOC of the battery 60 in an ignition switch OFF state and a difference between a charge amount of electricity and a discharge amount of electricity after the time of the ignition switch ON event. The SOC of the battery 60 in the ignition switch OFF state may be calculated based on an OCV (Open Circuit Voltage) that is obtained from the voltage sensor 64 in the ignition switch OFF state or immediately after the ignition switch ON event. Further, the SOC of the battery 60 may be corrected based on a temperature of the battery 60, etc. In the following, the calculation value of the SOC calculated by the SOC calculation part 141 is also referred to as “a pre-correction SOC”, hereinafter.

The calculation accuracy determination part 142 detects a decrease in the accuracy of the pre-correction SOC calculated by the SOC calculation part 141. It is noted that such a decrease of the accuracy results from a fact that an error is inevitably included in a detection current value of the current sensor 62 due to hardware related factors of the current sensor 62. A way of detecting the decrease in the accuracy of the pre-correction SOC calculated by the SOC calculation part 141 is arbitrary. For example, the calculation accuracy determination part 142 may detect the decrease in the accuracy of the pre-correction SOC based on the cumulative charge/discharge electricity amount. For example, the calculation accuracy determination part 142 may detect the decrease in the accuracy of the pre-correction SOC if the cumulative charge/discharge electricity amount exceeds a predetermined threshold Th2. This is because the effect due to a cumulative error cannot be neglected as the cumulative charge/discharge electricity amount becomes greater. Alternatively, from the same viewpoint, the calculation accuracy determination part 142 may detect the decrease in the accuracy of the pre-correction SOC based on lapsed time, travel distance, etc., from the time of the ignition ON event. Further, the calculation accuracy determination part 142 may consider a soak time. This is because the shorter the soak time becomes, the greater the decrease in the accuracy of the pre-correction SOC calculated based on the OCV at the time of the ignition ON event becomes. For example, the calculation accuracy determination part 142 may set the predetermined value Th2 such that the shorter the soak time becomes, the smaller the predetermined value Th2 becomes.

The calculation accuracy determination part 142 detects the decrease in the accuracy of the pre-correction SOC calculated by the SOC calculation part 141 in any number of steps. In the following, as an example, the calculation accuracy determination part 142 determines two states “a high accuracy state” and “a low accuracy state” (i.e., in two steps) with respect to the accuracy of the pre-correction SOC calculated by the SOC calculation part 141. For example, the calculation accuracy determination part 142 sets the high accuracy state at the time of the ignition switch ON event, and sets the low accuracy state if the cumulative charge/discharge electricity amount exceeds the predetermined value.

The correction value calculation part 143 calculates a correction value(s) for the pre-correction SOC calculated by the SOC calculation part 141. The correction values may include the first correction value Δ1 for high accuracy state and the second correction value Δ2 for low accuracy state. A way of calculating a first correction value Δ1 for high accuracy state is arbitrary. For example, the first correction value Δ1 for high accuracy state may be a constant value. The constant value may be adapted by experiments, etc. The correction value calculation part 143 may calculate the second correction value Δ2 for low accuracy state based on behavior of the charge current during the refresh charging. For example, the second correction value Δ2 for low accuracy state is a value according to a difference D between a first correction value α1 of the SOC calculated based on the behavior of the charge current in the charge late state during the refresh charging, and a second correction value α2 of the SOC calculated based on the voltage of the battery 60 at the same timing as the first correction value α1. In other words, the second correction value α2 corresponds to the SOC calculated by using the voltage of the battery 60 in the charge late state based on a relationship between the voltage of the battery 60 and the SOC. The second correction value α2 may correspond to the difference D or may be a value obtained by multiplying the difference D by a predetermined proportionality factor, for example. The first correction value α1 may be calculated based on the behavior (change manner in time series) of the charge current measured by the current sensor 62 according to a known charge characteristic of the battery 60, for example. The charge characteristic is related a relationship between the charge current and the SOC. The correction value calculation part 143 utilizes data representing the charge characteristic of the battery 60 measured in advance, for example.

The control SOC calculation part 144 calculates the control SOC based on the pre-correction SOC calculated by the SOC calculation part 141 and the correction value calculated by the correction value calculation part 143. At that time, the control SOC calculation part 144 changes the way of calculating the control SOC according to the accuracy determined by the calculation accuracy determination part 142. Specifically, in the high accuracy state, the control SOC calculation part 144 calculates the control SOC by subtracting the first correction value Δ1 for high accuracy state from the pre-correction SOC calculated by the SOC calculation part 141. In the low accuracy state, the control SOC calculation part 144 calculates the control SOC by subtracting the second correction value Δ2 for low accuracy state from the pre-correction SOC calculated by the SOC calculation part 141. However, even in the low accuracy state, as described hereinafter, if the pre-correction SOC calculated by the SOC calculation part 141 at the time of setting the low accuracy state is greater than a predetermined threshold Th1, the control SOC calculation part 144 calculates the control SOC by subtracting the first correction value Δ1 for high accuracy state from the pre-correction SOC calculated by the SOC calculation part 141 and further subtracting a predetermined accuracy reservation margin M from the pre-correction SOC from which the first correction value Δ1 for high accuracy state has been subtracted.

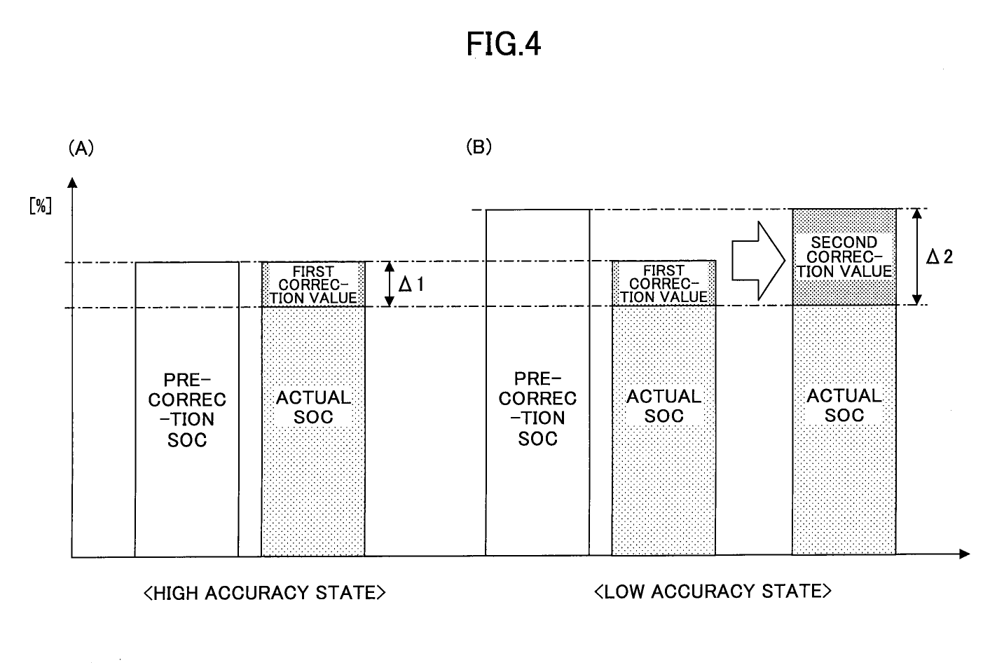

FIG. 4 is a diagram for explaining the first correction value Δ1 for high accuracy state and the second correction value Δ2 for low accuracy state, in which (A) illustrates an example of a relationship between the pre-correction SOC and an actual SOC in the high accuracy state, and (B) illustrates an example of a relationship between the pre-correction SOC and the actual SOC in the low accuracy state.

In the high accuracy state, as illustrated in FIG. 4 (A), an alienation between the pre-correction SOC and the actual SOC is relatively small because of the high accuracy state. In the example illustrated in FIG. 4 (A), the pre-correction SOC is calculated such that it is higher than the actual SOC. In the case of the high accuracy state, the control SOC is calculated by subtracting the first correction value Δ1 for high accuracy state from the pre-correction SOC, which can reduce the alienation between the control SOC and the actual SOC. It is noted that, in this example, the pre-correction SOC is calculated such that it is higher than the actual SOC; however, there may be a case where the pre-correction SOC is calculated such that it is lower than the actual SOC. In this case, the control SOC may be calculated by adding the first correction value Δ1 for high accuracy state to the pre-correction SOC.

In the low accuracy state, as illustrated in FIG. 4 (B), the alienation between the pre-correction SOC and the actual SOC is relatively great because of the low accuracy state. In the example illustrated in FIG. 4 (B), the pre-correction SOC is calculated such that it is higher than the actual SOC. At that time, as schematically illustrated in FIG. 4 (B), in the case of the low accuracy state, the control SOC is calculated by subtracting the second correction value Δ2 for low accuracy state from the pre-correction SOC. The second correction value Δ2 for low accuracy state is greater than the first correction value Δ1 for high accuracy state. Thus, even in the low accuracy state, the alienation between the control SOC and the actual SOC can be reduced. It is noted that, in this example, the pre-correction SOC is calculated such that it is higher than the actual SOC; however, there may be a case where the pre-correction SOC is calculated such that it is lower than the actual SOC. In this case, the control SOC may be calculated by adding the second correction value Δ2 for low accuracy state to the pre-correction SOC.

In this way, even if the calculation accuracy of the pre-correction SOC is decreased, the alienation between the control SOC and the actual SOC can be reduced by calculating the second correction value Δ2 for low accuracy state to correct the pre-correction SOC. With this arrangement, the fuel economy control execution propriety determination process based on the control SOC can be performed continuously. With this arrangement, even if the calculation accuracy of the pre-correction SOC is decreased, the reduction in the chance to perform the fuel economy control is suppressed. However, the calculation of the second correction value Δ2 for low accuracy state involves the refresh charging, as described above. This means that the fuel economy control is prevented during the calculation process of the second correction value Δ2 for low accuracy state. In other words, this means that there is a case where the chance to perform the fuel economy control is lost due to the calculation of the second correction value Δ2 for low accuracy state. In the following, a way of reducing the loss of the chance to perform the fuel economy control is described in detail.

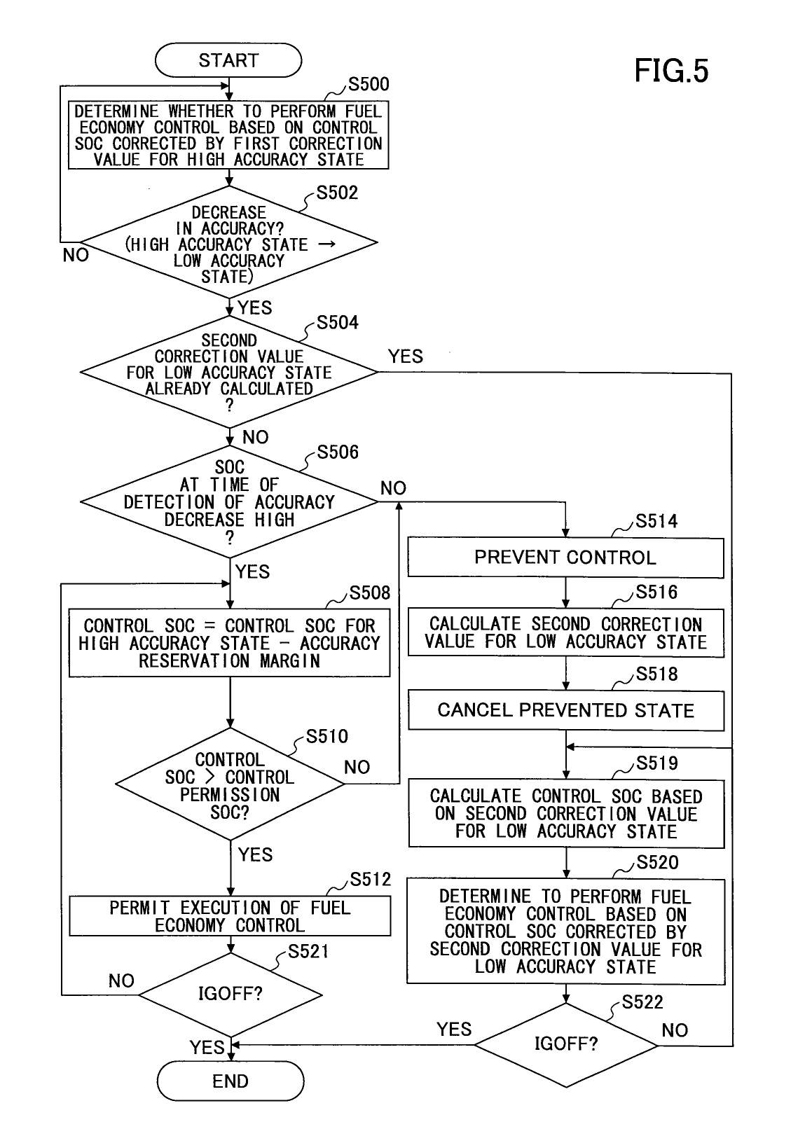

FIG. 5 is an example of a flowchart of a process executed by the charge control ECU 10. The process illustrated in FIG. 5 is initiated at the time of the ignition switch ON event, and then may be repeated at a predetermined cycle until the ignition switch is turned off (see “YES” step S521 or step S522).

In step S500, respective operations in the high accuracy state are performed. Specifically, the SOC calculation part 141 of the battery capacity calculation part 14 calculates the pre-correction SOC; the correction value calculation part 143 calculates the first correction value Δ1 for high accuracy state; and the control SOC calculation part 144 of the battery capacity calculation part 14 calculates the control SOC based on the first correction value Δ1 for high accuracy state. In the following, the control SOC calculated based on the first correction value Δ1 for high accuracy state is also referred to as “a control SOC for high accuracy state”, hereinafter. The fuel economy prevention part 18 performs the fuel economy control execution propriety determination process based on the control SOC for high accuracy state. In other words, the fuel economy prevention part 18 determines whether the control SOC for high accuracy state becomes less than or equal to the control permission SOC. The fuel economy prevention part 18 outputs a prevention instruction for preventing the execution of the fuel economy control if the control SOC for high accuracy state becomes less than or equal to the control permission SOC.

In step S502, the calculation accuracy determination part 142 of the battery capacity calculation part 14 determines whether the calculation accuracy of the pre-correction SOC is decreased. This determination way may be as described above. If the calculation accuracy of the pre-correction SOC is decreased, the calculation accuracy determination part 142 sets the low accuracy state, which causes the process to go to step S504. On the other hand, if the calculation accuracy of the pre-correction SOC is not decreased, the process returns to step S500 to repeatedly perform the respective operations in the high accuracy state.

In step S504, the correction value calculation part 143 determines whether the second correction value Δ2 for low accuracy state has already been calculated. Once the second correction value Δ2 for low accuracy state has been calculated, it may be cleared at the time of the ignition switch OFF event, or may be held over for a plurality of trips. If the second correction value Δ2 for low accuracy state has already been calculated, the process goes to step S519, otherwise the process goes to step S506.

In step S506, the control SOC calculation part 144 determines whether the control SOC (control SOC for high accuracy state) at the time of the detection of the decrease in the calculation accuracy is greater than the predetermined threshold Th1. The predetermined threshold Th1 corresponds to a value near the lower limit value of the range of the high accuracy state of the battery 60. The predetermined threshold Th1 is set based on design concepts. It is noted that, as a matter of course, the predetermined threshold Th1 is substantially greater than the control permission SOC. It is noted that, instead of determining whether the control. SOC at the time of the detection of the decrease in the calculation accuracy is greater than the predetermined threshold Th1, it may be determined whether the pre-correction SOC at the time of the detection of the decrease in the calculation accuracy is greater than a predetermined threshold Th1′ as an equivalent embodiment. Also in this case, the predetermined threshold Th1′ may be set based on the same concepts. Further, the control SOC at the time of the detection of the decrease in the calculation accuracy is not necessarily the control SOC for the accuracy state at the very time of the detection of the decrease in the calculation accuracy. The control SOC at the time of the detection of the decrease in the calculation accuracy has such a concept that it includes the control SOC before or after the detection of the decrease in the calculation accuracy as long as there is not a great difference with respect to the very time of the detection of the decrease in the calculation accuracy. In step S506, if the control SOC at the time of the detection of the decrease in the calculation accuracy is greater than the predetermined threshold Th1, the process goes to step S508, otherwise the process goes to step S514.

In step S508, the control SOC calculation part 144 calculates the control SOC by subtracting the predetermined accuracy reservation margin M from the control SOC for high accuracy state. Specifically, the control SOC calculation part 144 calculates the control SOC as follows. control SOC=control SOC for high accuracy state−accuracy reservation margin M. The accuracy reservation margin M may be arbitrary. The accuracy reservation margin M is set in a range less than or equal to a difference between the predetermined value Th1 and the control permission SOC. For example, the accuracy reservation margin M may be the previous value of the second correction value Δ2 for low accuracy state (if it is previously calculated). Alternatively, if a tolerance range of the alienation between the pre-correction SOC in the high accuracy state and the actual SOC (see FIG. 4 (A)) is ±X %, and a tolerance range of the alienation between the pre-correction SOC in the low accuracy state and the actual SOC (see FIG. 4 (A)) is ±Y (greater than X %), the accuracy reservation margin M may be equal to Y−X. It is noted that the control SOC calculation part 144 calculates the control SOC by subtracting a predetermined accuracy reservation margin M′ from the pre-correction SOC as an equivalent embodiment. In this case, the predetermined accuracy reservation margin M′ may be set such that it is greater than the first correction value Δ1 for high accuracy state that otherwise is subtracted from the pre-correction SOC.

In step S510, the fuel economy prevention part 18 performs the fuel economy control execution propriety determination process based on the control SOC calculated in step S508. In other words, the fuel economy prevention part 18 determines whether the control SOC calculated in step S508 is greater than the control permission SOC. If the control SOC calculated in step S508 is greater than the control permission SOC, the process goes to step S512, otherwise the process goes to step S514.

In step S512, the fuel economy prevention part 18 permits the execution of the fuel economy control. For example, the fuel economy prevention part 18 does not output the prevention instruction for preventing the fuel economy control. Thus, if the execution condition of the fuel economy control is met, the fuel economy control is performed. It is noted that, if the permission for the execution of the fuel economy control is implemented by not outputting the prevention instruction, the process of step S512 may be omitted in the software program.

In step S514, the fuel economy prevention part 18 outputs the prevention instruction for preventing the fuel economy control. This output process of the prevention instruction is for calculating the second correction value Δ2 for low accuracy state in the next process of step S516. This is because the calculation of the second correction value Δ2 for low accuracy state involves the refresh charging, as described above. In other words, this is because, in order to calculate the second correction value Δ2 for low accuracy state, the behavior of the charge current during the refresh charging needs to be detected.

In step S516, the correction value calculation part 143 calculates the second correction value Δ2 for low accuracy state. The way of calculating the second correction value Δ2 for low accuracy state may be as described above.

In step S518, the fuel economy prevention part 18 cancels the prevented state formed in step S514. It is noted that the calculation process of the second correction value Δ2 for low accuracy state by the correction value calculation part 143 (step S516) takes time to some extent. Thus, the fuel economy prevention part 18 waits for the completion of the calculation of the second correction value Δ2 for low accuracy state by the correction value calculation part 143, and cancels the prevented state after the completion of the calculation of the second correction value Δ2 for low accuracy state by the correction value calculation part 143.

In step S518, the control SOC calculation part 144 calculates the control SOC based on the second correction value Δ2 for low accuracy state calculated in step S516. The way of calculating the control SOC for low accuracy state based on the second correction value Δ2 for low accuracy state may be as described above.

In step S520, the fuel economy prevention part 18 performs the fuel economy control execution propriety determination process based on the control SOC calculated in step S519. In other words, the fuel economy prevention part 18 determines whether the control SOC calculated in step S519 is less than or equal to the control permission SOC. If the control SOC calculated in step S519 is less than or equal to the control permission SOC, the fuel economy prevention part 18 outputs the prevention instruction for preventing the execution of the fuel economy control. On the other hand, if the control SOC calculated in step S519 is greater than the control permission SOC, the fuel economy prevention part 18 does not output the prevention instruction (i.e., forms the permitted state). Thus, if the execution condition of the fuel economy control is met, the fuel economy control is performed.

In step S521, the control SOC calculation part 144 determines whether the ignition switch is turned off. If the ignition switch is turned off, the process ends correspondingly (forced to end), and otherwise the process returns to step S508 to repeat the processes using the newly obtained pre-correction SOC.

In step S522, the fuel economy prevention part 18 determines whether the ignition switch is turned off. If the ignition switch is turned off, the process ends correspondingly (forced to end), and otherwise the process returns to step S519 to repeat the processes using the newly obtained pre-correction SOC.

According to the process illustrated in FIG. 5, if the decrease in the calculation accuracy of the pre-correction SOC is detected, the fuel economy control execution propriety determination process can be continued by using the control SOC based on the second correction value Δ2 for low accuracy state. Thus, the reduction in the chance to perform the fuel economy control can be suppressed. However, the calculation of the second correction value Δ2 for low accuracy state involves the refresh charging, as described above, which means that there is a case where the chance to perform the fuel economy control is lost due to the calculation of the second correction value Δ2 for low accuracy state.

With respect to this, according to the process illustrated in FIG. 5, even if the decrease in the calculation accuracy of the pre-correction SOC is detected, the second correction value Δ2 for low accuracy state is not calculated to continue the fuel economy control execution propriety determination process using the control SOC based on the accuracy reservation margin M, if the control SOC at the time of the detection of the decrease in the calculation accuracy is greater than the predetermined value Th1. Thus, the loss of the chance to perform the fuel economy control due to the calculation of the second correction value Δ2 for low accuracy state can be suppressed. Further, the control SOC based on the accuracy reservation margin M is used as long as the control SOC at the time of the detection of the decrease in the calculation accuracy is greater than the predetermined value Th1, which can ensures the reservation of the battery 60 when the SOC is the battery 60 is low. Further, the control SOC based on the accuracy reservation margin M is calculated such that it is smaller than the control SOC for high accuracy state, and thus the fuel economy control in case of using the control SOC based on the accuracy reservation margin M is prevented earlier than that in the case of using the control SOC for high accuracy state. Thus, even if the control SOC based on the accuracy reservation margin M is used, it is possible to increase a probability that the fuel economy control is prevented before the actual SOC of the battery 60 becomes less than or equal to the control permission SOC.

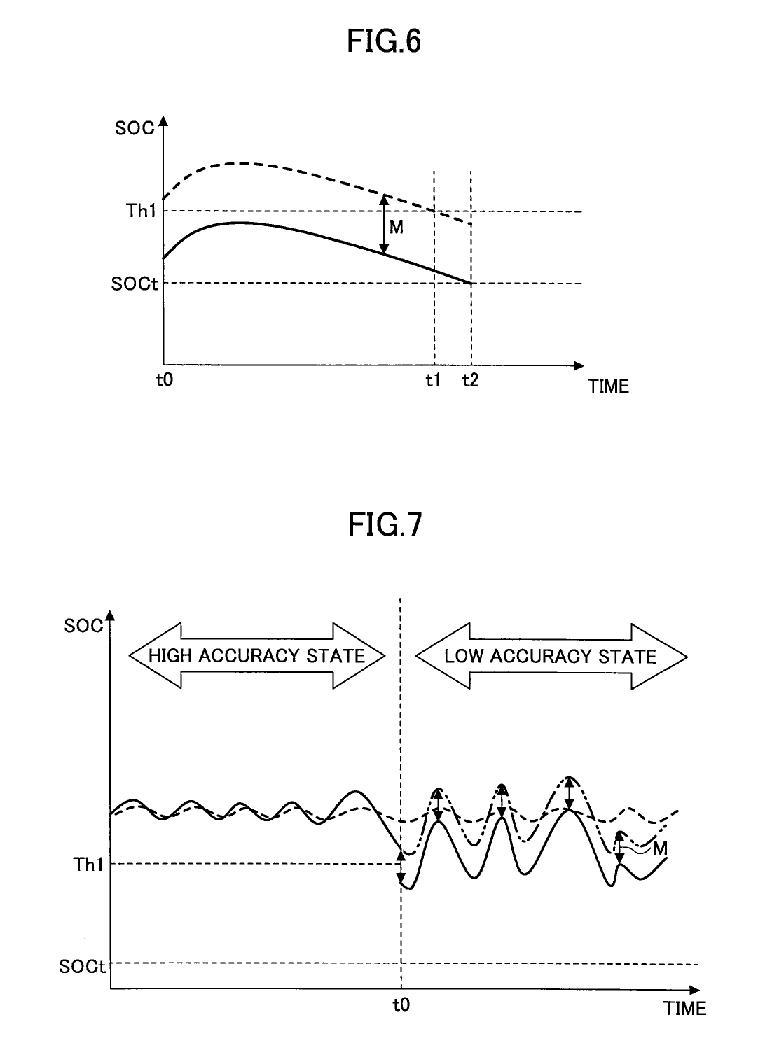

It is noted that, according to the process illustrated in FIG. 5, if the determination result in step S506 is “YES”, and thus the process goes to step S508, the process goes to step S514 if the control SOC based on the accuracy reservation margin M becomes less than or equal to the control permission SOC (if the determination result in step S510 is “NO”). However, if the determination result in step S506 is “YES”, and thus the process goes to step S508, the process may go to step S514 if the control SOC for high accuracy state becomes less than or equal to the predetermined value Th1 (see time point t1 in FIG. 6).

FIG. 6 is a diagram illustrating an example of a change in time series of the control SOC based on the accuracy reservation margin M and the SOC for high accuracy state control. In FIG. 6, the control SOC based on the accuracy reservation margin M is indicated by a solid line, and the control SOC for high accuracy state is indicated by a dotted line. Further, the control permission SOC is indicated by “SOCt”.

In the example illustrated in FIG. 6, the decrease in the calculation accuracy of the pre-correction SOC is detected at time point t0. At that time, the control SOC (control SOC for high accuracy state) is greater than the predetermined value Th1, and thus the determination result in step S506 in FIG. 5 is affirmative. Thus, after that, the control SOC based on the accuracy reservation margin M is calculated (step S508). After that, the control SOC based on the accuracy reservation margin M becomes less than or equal to the control permission SOC at time point t2. In this case, the determination result in step S510 in FIG. 5 is negative, and thus the calculation process of the second correction value Δ2 for low accuracy state is performed (step S516). It is noted that, as described above, instead of the time point t2 when the control SOC based on the accuracy reservation margin M becomes less than or equal to the control permission SOC, the calculation process of the second correction value Δ2 for low accuracy state may be performed at time point t1 when the control SOC for high accuracy state becomes less than or equal to the predetermined value Th1.

FIG. 7 is a diagram illustrating an example of the change in time series of the control SOC in the high accuracy state and the low accuracy state. In FIG. 7, the control SOC is indicated by a solid line, the actual SOC is indicated by a dotted line, and an imaginary control SOC for high accuracy state is indicated by a chain double-dashed line. Further, the control permission SOC is indicated by “SOCt”.

In the example illustrated in FIG. 7, the high accuracy state is formed before the time point t0. In this case, as illustrated in FIG. 7, the alienation between the actual SOC and the control SOC is small. The alienation between the actual SOC and the control SOC basically becomes greater according to a lapse of time. The decrease in the calculation accuracy of the pre-correction SOC is detected at time point t0, and the control SOC (control SOC for high accuracy state) at that time is greater than the predetermined value Th1. For this reason, the control SOC is changed at the time point t0 from the control SOC based on the first correction value Δ1 for high accuracy state to the control SOC based on the accuracy reservation margin M. In other words, the control SOC is changed to a value (i.e., the control SOC based on the accuracy reservation margin M) that is smaller than the control SOC for high accuracy state (indicated by the chain double-dashed line) by the accuracy reservation margin M. In the example illustrated in FIG. 7, the control SOC based on the accuracy reservation margin M is greater than the control permission SOC afterward, and thus a state in which the fuel economy control is executable is formed during this period.

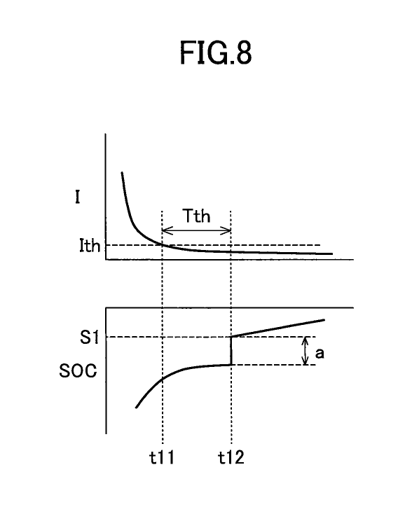

FIG. 8 is a timing chart illustrating an example of a way of calculating the second correction value Δ2 for low accuracy state based on a behavior of a charge current I of the battery 60. The way illustrated in FIG. 8 may be used for the process in step S516 in FIG. 5, for example. FIG. 8 illustrates a course of charging the battery 60 to the charge late state in which the charge current I of the battery 60 becomes less than a predetermined value Ith. The state of the battery 60 in the charge late state corresponds to a substantially fully charged state (greater than or equal to 90%, for example) just before a fully charged state.

For example, in the case where the battery 60 is charged under a charge condition of a constant low current and at a constant high voltage over a relatively long period, when the state of the battery 60 reaches the substantially fully charged state, the current value of the charge current I suddenly decreases and the charge current I after timing t11 becomes smaller than a predetermined current value Ith. After the timing t11, if the battery 60 is continuously charged under the same condition, a change rate of the charge current I becomes less than or equal to a predetermined decrease rate and a change rate of the SOC becomes less than or equal to a predetermined increase rate.

The battery 60 has such a charge characteristic that the SOC is equal to a constant coefficient S1 (95%, for example) at timing t12 that is after a constant time Tth (two minutes, for example) has passed from the timing t11 when the charge current I becomes smaller than the predetermined current value Ith (3 A, for example).

Thus, the correction value calculation part 143 charges the battery 60 under a charge condition of a constant low current and at a constant high voltage over a relatively long period, and calculates an offset amount “a”, as the second correction value Δ2 for low accuracy state, between the coefficient S1 and the pre-correction SOC at the time when a constant time Tth has passed since the charge current I becomes smaller than the predetermined current value Ith. Thus, in the case of FIG. 8, the control SOC calculation part 144 calculates the control SOC (=coefficient S1) that is obtained by adding the offset amount “a” to the pre-correction SOC at the timing t12.

According to the way of calculating the second correction value Δ2 for low accuracy state illustrated in FIG. 8, it is possible to correct the pre-correction SOC with high accuracy even in the low accuracy state, by correcting the second correction value Δ2 for low accuracy state based on the behavior of the charge current I in the charge late state.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention. Further, all or part of the components of the embodiments described above can be combined.

For example, according to the embodiments described above, at the time of the detection of the decrease in the accuracy of the pre-correction SOC, the control SOC is calculated by subtracting the accuracy reservation margin M from the control SOC for high accuracy state, and the fuel economy control is permitted if the calculated control SOC is greater than the control permission SOC. However, as an equivalent embodiment, at the time of the detection of the decrease in the accuracy of the pre-correction SOC, the control permission SOC may be corrected while continuously using the control SOC for high accuracy state. In this case, the control permission SOC is corrected by adding the accuracy reservation margin M thereto. In this case, the fuel economy control may be permitted if the control SOC for high accuracy state is greater than the corrected control permission SOC. Alternatively, the control permission SOC may be corrected while calculating the control SOC by subtracting the accuracy reservation margin M from the control SOC for high accuracy state.

Further, according to the embodiments described above, the fuel economy prevention part 18 prevents or permits the charge control and the idling stop control; however, only one of the charge control and the idling stop control may be prevented. Further, the fuel economy prevention part 18 may prevent only a part of the charge control that involves the discharge.

Further, according to the embodiments described above, the control SOC calculation part 144 calculates the control SOC in the high accuracy state by correcting the pre-correction SOC with the first correction value Δ1 for high accuracy state; however, such a correction in the high accuracy state may be omitted. For example, the battery capacity calculation part 14 may calculate the pre-correction SOC as the control SOC in the high accuracy state.

Further, according to the embodiments described above, the calculation of the second correction value Δ2 for low accuracy state involves the refresh charging; however, the refresh charging at that time may be performed differently with respect to an ordinary refresh charging. For example, in the case of the ordinary refresh charging, a refresh charging end condition may be met if the state of the battery 60 reaches a predetermined overcharged state (the overcharged state required for the life preservation of the battery 60). On the other hand, in the case of the refresh charging performed to calculate the second correction value Δ2 for low accuracy state, the refresh charging end condition may be met if the calculation of the second correction value Δ2 for low accuracy state is completed.

The present application is based on Japanese Priority Application No. 2014-102753, filed on May 16, 2014, the entire contents of which are hereby incorporated by reference.

What is claimed is:

1. A vehicle control apparatus comprising:
a sensor that obtains information related to a SOC (State Of Charge) of a battery; and
a processing device that calculates the SOC based on the information from the sensor; determines whether the calculation value of the SOC is greater than a predetermined threshold; and permits an execution of control that involves a discharge of the battery if the calculation value of the SOC is greater than the predetermined threshold, wherein
when the processing device detects a decrease in accuracy of the calculation value of the SOC, the processing device determines whether the calculation value of the SOC at a time of detection of the decrease is greater than a predetermined value that is greater than the predetermined threshold, and if the calculation value of the SOC at a time of detection of the decrease is greater than the predetermined value, the processing device corrects at least one of the calculation value of the SOC and the predetermined threshold to continue the determination with the predetermined threshold, wherein at least one of the calculation value of the SOC and the predetermined threshold is corrected such that the execution of the control is permitted more difficulty, within a range in which the execution of the control can be permitted, with respect to a state before the detection of the decrease.

2. The vehicle control apparatus of claim 1, wherein the processing device prevents the execution of the control if the calculation value of the SOC at a time of the detection of the decrease is less than or equal to the predetermined value.

3. The vehicle control apparatus of claim 1, wherein if the calculation value of the SOC at a time of the detection of the decrease is greater than the predetermined value, the processing device corrects the calculation value of the SOC by subtracting a correction value therefrom.

4. The vehicle control apparatus of claim 3, wherein the processing device prevents the execution of the control if the corrected calculation value of the SOC is less than or equal to the predetermined value.

5. The vehicle control apparatus of claim 2, wherein if the processing device prevents the execution of the control, the processing device calculates, during a period of the prevention, a second correction value for the calculation value of the SOC.

6. The vehicle control apparatus of claim 5, wherein the processing device executes a charging process that causes the SOC of the battery to increase to a maximum value during the period of the prevention, and calculates the second correction value based on a change manner of a charge current of the battery in time series during the charging process.

7. The vehicle control apparatus of claim 6, wherein the processing device cancels the prevention after the calculation of the second correction value; corrects the calculation value of the SOC with the second correction value; and performs the determination with the predetermined threshold based on the calculation value of the SOC calculated with the second correction value.

8. The vehicle control apparatus of claim 4, wherein if the processing device prevents the execution of the control, the processing device calculates, during a period of the prevention, a second correction value for the calculation value of the SOC.

9. The vehicle control apparatus of claim 8, wherein the processing device executes a charging process that causes the SOC of the battery to increase to a maximum value during the period of the prevention, and calculates the second correction value based on a change manner of a charge current of the battery in time series during the charging process.

10. The vehicle control apparatus of claim 9, wherein the processing device cancels the prevention after the calculation of the second correction value; corrects the calculation value of the SOC with the second correction value; and performs the determination with the predetermined threshold based on the calculation value of the SOC calculated with the second correction value.

11. The vehicle control apparatus of claim 1, wherein the processing device calculates a time integration value that is obtained by a time integration of absolute values of a charge current and a discharge current of the battery after an ignition switch on event, and detects the decrease in accuracy of the calculation value of the SOC if the time integration value exceeds a second predetermined threshold.
